(19) United States
(12) Patent Application Publication
(10) Pub. No.: US 2007/0247938 A1
(43) Pub. Date: Oct. 25, 2007

(54) Separate sense amplifier precharge node in a semiconductor memory device

(76) Inventors: Christopher Miller, Underhill, VT (US); Andre Sturm, Essex Junction, VT (US)

Correspondence Address: EDELL, SHAPIRO & FINNAN, LLC, 1901 RESEARCH BLVD., SUITE 400, ROCKVILLE, MD, 20850, US

(21) Appl. No.: 11/410,255

(22) Filed: Apr. 25, 2006

(51) Int. Cl. G11C 7/02

(52) U.S. Cl. 365/207

(57) ABSTRACT

A method and memory device are provided in which sense nodes of a sense amplifier in a semiconductor memory device are internally precharged independent of equalize and precharge operations on bitlines of a memory array associated with the sense amplifier.

### BACKGROUND OF THE INVENTION

In semiconductor memory devices, such as dynamic random access memory (DRAM) devices, a sense amplifier is provided to sense charge from storage cells in a memory array. In one type of semiconductor memory device, the sense amplifier is shared by two memory arrays arranged on opposite sides of the sense amplifier. Such a conventional sense amplifier configuration is shown in FIG. 1 in which sense amplifier 10 is shared by a first memory array 20 on the “t” side of the sense amplifier 10 and a second memory array 30 on a “b” side of the sense amplifier 10. On the “t” side of the sense amplifier 10 there is a multiplexer 40 and a restore circuit 50 between the sense amplifier and the bitlines (BLs) associated with the first memory array 20. Similarly, on the “b” side of the sense amplifier 10 there is a multiplexer 60 and an restore circuit 70. The multiplexer 40 controls the connection and disconnection of the sense amplifier 10 to the bitline (BL) pairs 12 and 14 on the “t” side and the multiplexer 60 controls the connection and disconnection of the sense amplifier 10 to the BL pairs 34 and 36 on the “b” side. Each BL pair comprises a BL and BL complement (/BL) node.

For each BL pair 12 14, the restore circuit 50 comprises a charging transistor pair 54 and an equalization transistor 56. The transistors in the charging transistor pair 54 are connected to respective ones of the BL in the BL pairs 12 and 14 to charge those BLs to a desired voltage. The equalization transistor 56 is connected across the BL and /BL nodes to short the nodes and bring them to the same voltage. The restore circuit 70 similarly has charging transistor pair 74 and equalization transistor 76 for each BL pair 34 and 36. Thus, each of the restore circuits 50 and 70 perform a precharging function and an equalization function for the BL pairs on their respective sides of the sense amplifier 10.

With reference to FIG. 2, operation of the sense amplifier configuration shown in FIG. 1 when sensing the “b” side array is as follows. The sense amplifier 10 is selectively connected to BLs leading to one of the memory arrays 20 or 30 by enabling the corresponding multiplexer 40 or 60 when a block select signal (BLKSEL) for one block in the memory device containing memory arrays 20 and 30 is activated. When the block is unselected, both multiplexer circuits 40 and 60 are weakly on, connecting the BLs on both sides of the sense amplifier to precharge sense amplifier nodes. However, when the block is selected (in this case side “b”), the multiplexer 60 turns on when the multiplexer control signal MUXb goes high in order to sense from memory array 30 on the “b” side of the sense amplifier 10. During this time, the multiplexer control signal MUXt goes low in order to isolate the memory array 20 on the “t” side from the sense amplifier 10.

When there is an anomalous bitline leakage that may be due to defects (e.g., resistive short-circuits), excessive junction leakage, or other causes, the leakage current may cause the BL to be pulled to a lower voltage, possibly a negative voltage determined by the negative wordline low potential (V_{NWL}). If the leakage current pulls the BL to a sufficiently low potential a current may pass from out of the sense amplifier nodes and into the V_{NWL} supply. To date, this problem has not been addressed. Maintaining BL connections on both or one side of the sense amplifier continues to permit a leakage path from the sense amplifier to the BL when BLs are shorted to the wordlines (WLs).

Accordingly, it would be desirable to eliminate the need to keep the multiplexer on in order to precharge the sense amplifier nodes and completely eliminate the leakage path from the internal sense node of the sense amplifier to the shorted BL when the memory array is unselected.

### SUMMARY OF THE INVENTION

Briefly, a method and memory device are provided in which sense nodes of a sense amplifier associated with a memory array in a semiconductor memory device are internally precharged independent of equalize and precharge operations on bitlines associated with the memory array.

### BRIEF DESCRIPTION OF THE DRAWINGS

FIG. 1 is a schematic diagram of a conventional sense amplifier configuration for a semiconductor memory device.

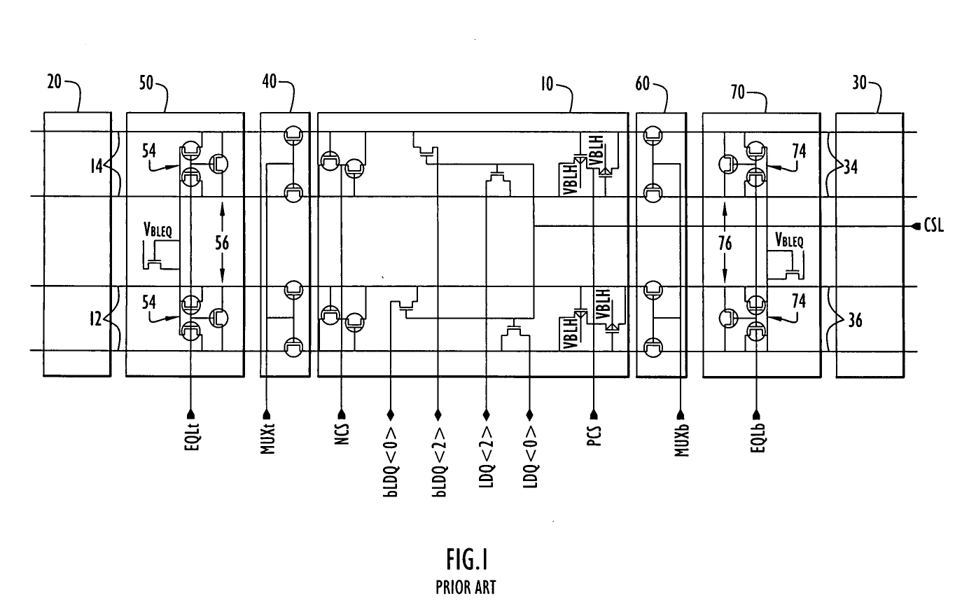

FIG. 2 is a timing diagram showing operation of the conventional sense amplifier configuration shown in FIG. 1.

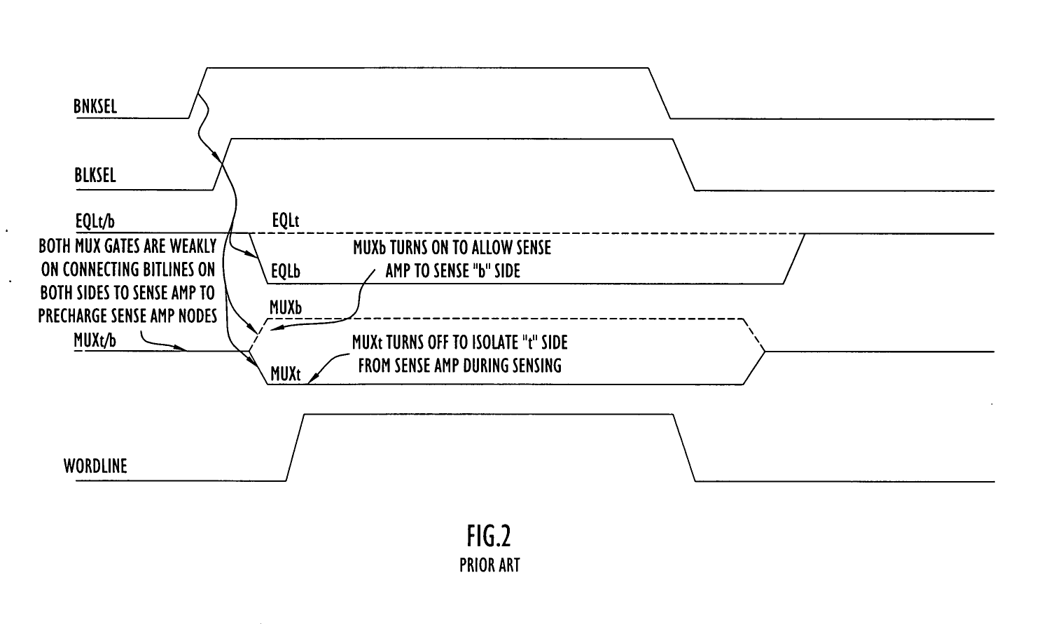

FIG. 3 is a schematic diagram of a sense amplifier having a restore circuit connected to the sense amplifier internal sense nodes according to an embodiment of the invention.

FIG. 4 is a timing diagram showing operation of the sense amplifier configuration shown in FIG. 3 according to an embodiment of the invention.

FIG. 5 is a schematic diagram of a sense amplifier configuration according to another embodiment of the invention.

FIG. 6 is timing diagram showing operation of the sense amplifier configuration shown in FIG. 5 according to an embodiment of the invention.

FIG. 7 is a schematic diagram of a sense amplifier configuration according to still another embodiment of the invention.

FIG. 8 is a timing diagram showing operation of the sense amplifier configuration shown in FIG. 7 according to an embodiment of the invention.

### DETAILED DESCRIPTION

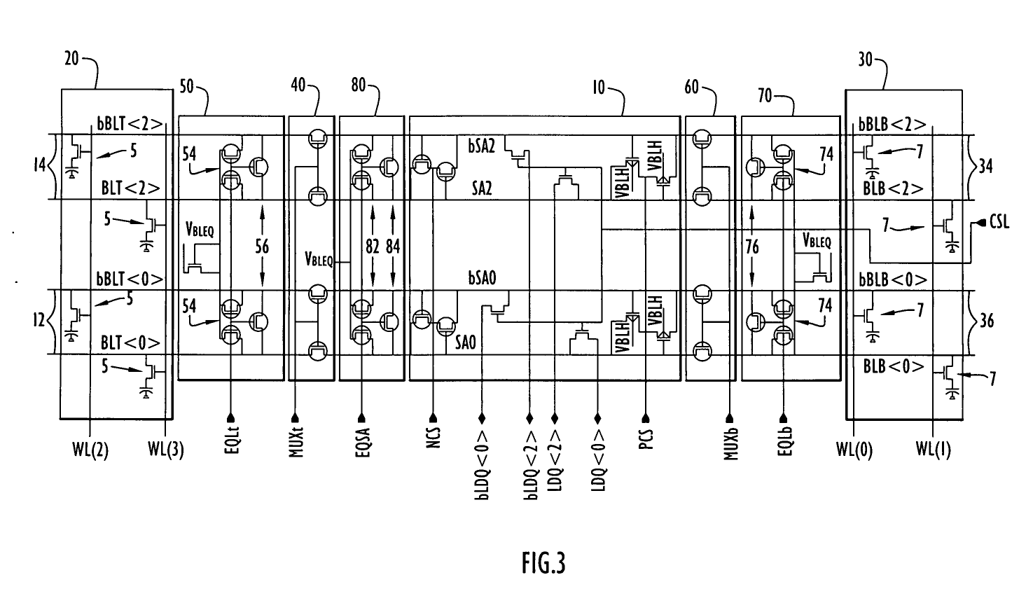

Referring first to FIG. 3, a sense amplifier configuration according to an embodiment of the invention is described. An additional internal restore circuit shown at reference numeral 80 is provided. The restore circuit 80 is dedicated to precharging and equalizing internal nodes of the sense amplifier 10, but may be used to perform additional functions as described hereinafter according to embodiments of the invention. In addition, in some embodiments described herein, the internal restore circuit 80 and the “external” restore circuits 50 and 70 include the capability to perform only the precharging function.

According to one embodiment, the restore circuit 80 comprises a charging transistor pair 82 and an equalization transistor 84 for each of the sense amplifier node pairs. The charging transistor pair 82 comprises first and second transistors that are controlled to connect to respective ones of the sense amplifier nodes bSA2 and SA2. The equalization transistor 84 is controlled to connect across the sense nodes bSA2 and SA2 of the sense amplifier sense node pair. There is also a charging transistor pair 82 (comprised of first and second transistors) that is controlled to connect to respective ones of the sense amplifier nodes bSA0 and SA0 and an equalization transistor 84 that is controlled to connect across the sense amplifier sense nodes bSA0 and SA0. FIG. 3 shows that the restore circuit 80 is positioned on the “t” side of the sense amplifier 10 but it should be understood that it may be positioned on the “b” side of the sense amplifier 10 just as well. In the embodiment shown in FIG. 3, the restore circuit 80 performs both precharging functions via charging transistor pair 82 and equalization functions via equalization transistor 84, for each sense amplifier sense node pair associated therewith.

In one embodiment, the first memory array 20 on the “t” side of the sense amplifier 10 comprises memory cells 5 and the second memory array 30 on the “b” side comprises memory cells 7. Even WLs are connected to “bBLs” in the BL pairs 12 and 14 via cells 5 on the “t” side and in the BL pairs 34 and 36 via cells 7 on the “b” side. That is, WL WL(0) connects to bBLB<2> and bBLB<0> via cells 7 on the “b” side and WL WL(2) connects to bBLT<2> and bBLT<0> on the “t” side via cells 5. On the other hand, WL WL(1) connects to BLB<2> and BLB<0> via cells 7 on the “b” side and WL WL(3) connects to BLT<2> and BLT<0> on the “t” side via cells 5. The multiplexer 40 controls connection of the sense amplifier 10 to the BL pairs 12 and 14 associated with the first memory array 20 and the multiplexer 60 controls connection of the sense amplifier 10 to the BL pairs 34 and 36 associated with the second memory array 30. The restore circuits 50 and 70 perform conventional precharge and equalization functions.

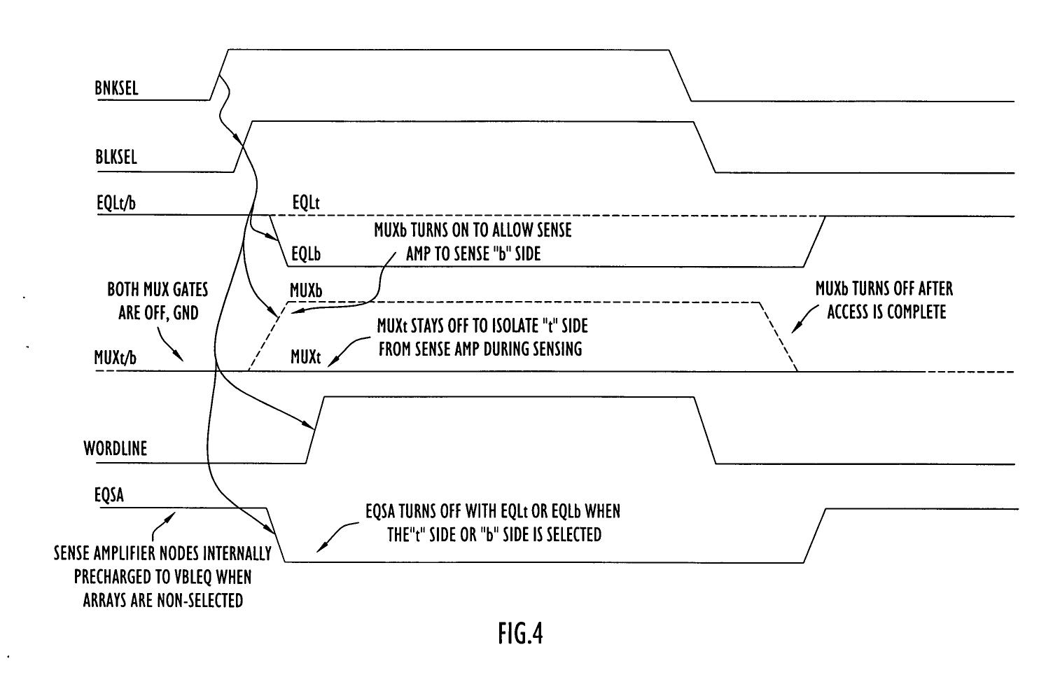

Turning to FIG. 4, with continued reference to FIG. 3, operation of the sense amplifier configuration shown in FIG. 3 will be described according to one embodiment. When the block is not selected (BLKSEL is low), the multiplexer control signals MUXt and MUXb are both low so that multiplexers 40 and 60 are both turned off. Consequently, if there is a short in either array 20 and 30 (or in both), any leakage current pulling a BL to a low voltage is prevented from drawing current from sense amplifier 10 because the multiplexers 40 and 60 are turned off and consequently there is no path through them to the sense amplifier nodes. When both arrays 20 and 30 are not selected, the internal restore circuit control signal EQSA is high, activating the restore circuit 80 so that the sense amplifier node pairs (bSA<2>, SA<2> and bSA<0> and SA<0>) are internally precharged and equalized by the first and second circuit portions 82 and 84, respectively, of the restore circuit 80.

When one of the memory arrays is selected, only the multiplexer associated with that selected memory is turned on. In the exemplary embodiment shown in FIG. 4, memory array 30 is selected and the multiplexer control signal MUXb goes high, turning on multiplexer 60 to connect the sense amplifier 10 to the memory array 30. The multiplexer control signal MUXt stays low so that the multiplexer 40 is turned off and therefore continues isolating the “t” side (array 20) from sense amplifier 10. The internal restore circuit control signal EQSA goes low together with the restore control circuit signals EQLb, thereby deactivating the restore circuit 80. After the access to the selected memory array is complete, the activated multiplexer is turned off and the internal restore circuit control signal EQSA goes high again to precharge the sense amplifier sense nodes while EQLb also goes high to precharge the bitlines on the “b” side. This exemplary embodiment is shown in FIG. 4 is where the multiplexer control signal MUXb goes low, turning off multiplexer 60.

By providing a separate and dedicated restore circuit for the sense nodes of the sense amplifier 10, both multiplexers 40 and 60 may be turned off (disabled) indefinitely when both arrays are not selected without concern for maintaining sense amplifier node voltage levels. Moreover, the sense nodes of the sense amplifier 10 are internally precharged independent of equalize and precharge operations on bitlines associated with the memory arrays on opposite sides of the sense amplifier 10. Conversely, the restore circuits 50 and 70 are controllable to precharge the respective bitline pairs independent of precharge operations performed by the internal restore circuit 80 on the sense node pair.

In addition, precharge voltage on the sense amplifier sense nodes is maintained independent of a precharge operation on bitlines of the memory arrays. The leakage current drawn from the sense amplifier 10 caused by a defect in one or both of the arrays 20 and 30 is eliminated. A leakage limiter device for the internal sense amplifier nodes in the restore circuit 80 is not needed (as in the restore circuits 50 and 70) because the leakage path is blocked by turning off both multiplexers. In addition, it is no longer necessary to test a memory device in order to interrogate and determine which side of the sense amplifier has a leakage current (resulting from a BL leakage anomaly in the unselected array) in order to isolate it from the sense amplifier when that side is not selected. This is because the precharge voltage is supplied by devices internal (and dedicated) to the sense amplifier sense nodes. As a result, it is not necessary to blow a fuse to indicate which side of the sense amplifier has a defect for purposes of setting the isolation control signal logic. Thus, the need to keep one of the multiplexers on in order to precharge the sense amplifier nodes is eliminated. However, the current reduction benefit of isolating a memory array having a defect from the sense amplifier is still achieved by the embodiments of the present invention.

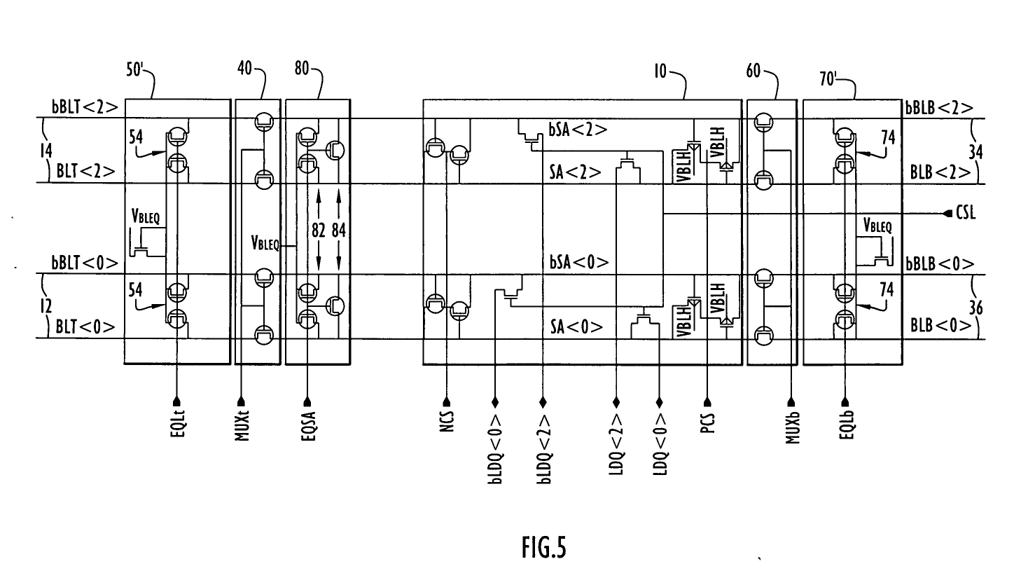

According to further embodiments of the invention, the restore circuit 80 may serve to perform bitline and sense amplifier equalization through a selected multiplexer circuit as shown in the embodiments of FIGS. 5-8.

FIG. 5 shows an embodiment in which restore circuits 50′ and 70′ are similar to those circuits shown in FIG. 3 except that they do not include an equalization transistor for the bitlines. As a result, equalization of the bitlines is performed by the equalization transistors 84 of the restore circuit 80. The bitline pairs 12,14 and 34,36 associated with the memory arrays (not shown in FIG. 5) on opposite sides of the sense amplifier 10 are equalized by equalization transistors 84 through multiplexers 40 and 60. For example, multiplexer 40 is controlled to connect equalization transistor 84 to bitlines bBLT<2> and BLT<2> of bitline pair 14 and to connect the other equalization transistor 84 to bitlines bBLT<0> and BLT<0> of bitline pair 12. Similarly, multiplexer 60 may be controlled to connect equalization transistor 84 to bitlines bBLB<2> and BLB<2> of bitline pair 34 to equalize the voltage on those bitlines, and to connect the other equalization transistor 84 to bitlines bBLB<0> and BLB<0> of bitline pair 36 to equalize the voltage on those bitlines.

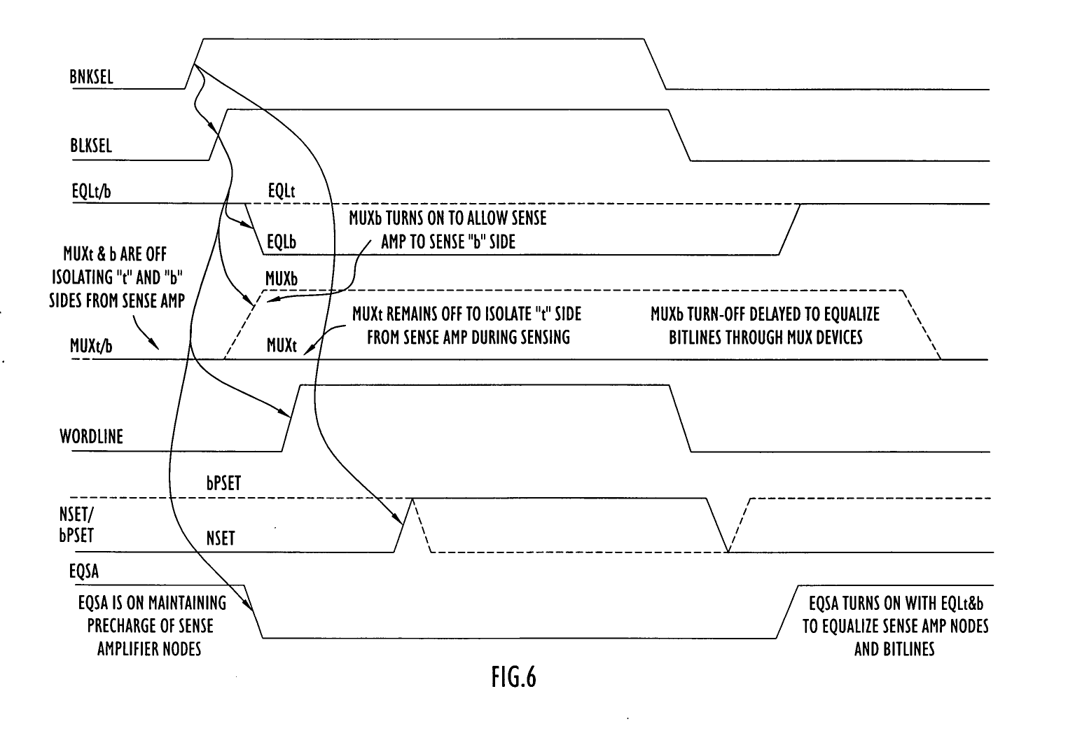

FIG. 6 illustrates a timing diagram for the bitline equalization function of the embodiment shown in FIG. 5. In this example, both of the multiplexer circuits 40 and 60 are initially off, isolating both the “t” side and “b” side of the sense amplifier 10, but then the “b” side of the sense amplifier 10 is to be accessed so MUXb goes high while MUXt says low. Also, the internal restore circuit control signal EQSA is on while MUXb and MUXt are off to maintain precharge of the sense amplifier nodes as described in the previous embodiments. EQSA goes low when MUXb goes high. After access of the “b” side array is made, EQLb and EQSA go high to precharge and equalize BLs and the sense amplifier nodes. MUXb is turned off only after an extended time interval (or in other words kept on for an extended time period) in order for transistors 84 of the restore circuit 80 to equalize voltage on the bitlines of the “b” side array through the multiplexer circuit 60. Thus, FIG. 5 shows one exemplary embodiment where when an array returns to a non-selected state, the corresponding multiplexer control signal (MUXt or MUXb) can be timed to connect the equalization transistors 84 in the internal restore circuit 80 to the bitlines on that previously selected side of the sense amplifier. This allows for eliminating a transistor in one or both of the restore circuits shown at reference numerals 50′ and 70′ in FIG. 5.

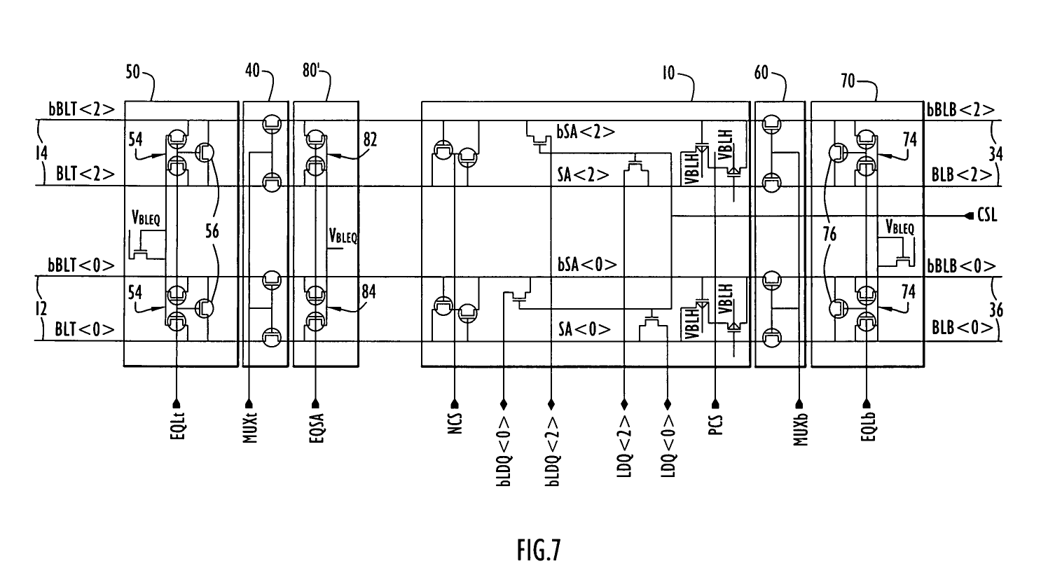

FIG. 7 illustrates another embodiment in which the restore circuit 80′ is simplified so as not to include the transistors 84. Instead, the equalization transistors 56 and 76 are included in the restore circuits 50 and 70, respectively, and one of these pairs of equalization transistors is used to perform the equalization function on the sense amplifier sense nodes.

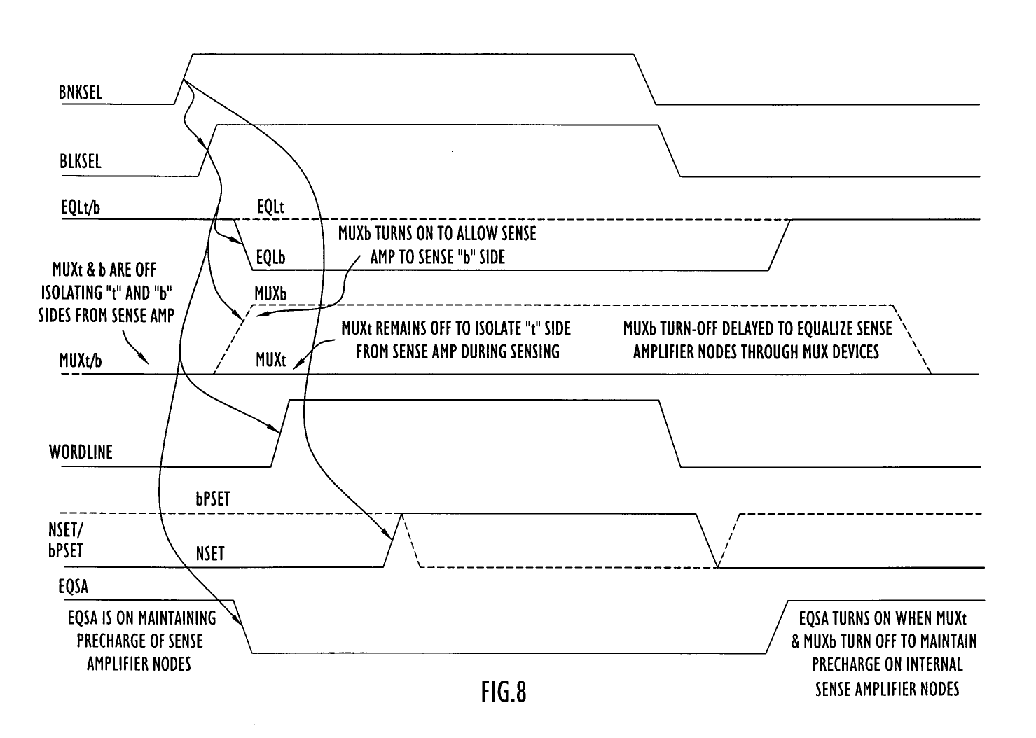

FIG. 8 illustrates a timing diagram for operation of the embodiment shown in FIG. 7. This timing diagram is similar to the one shown in FIG. 6, where both the “b” and “t” sides of the sense amplifier are being isolated and then the “b” side is selected for access. Turn off of the MUXb control signal is delayed so that the multiplexer 60 remains on for an extended time interval in order to allow the equalization transistors 76 to remain connected to the sense amplifier sense nodes to precharge them through the multiplexer circuit 60. The EQSA signal turns on to maintain precharge on the internal sense amplifier nodes after MUXb turns off. It should be understood that the “t” side of the sense amplifier could likewise be used to equalize the sense amplifier sense nodes through multiplexer 40 using the equalization transistors 56.

Thus, the embodiment of FIGS. 5 and 6 show how the restore circuits 50 and 70 can be simplified (by removing the equalization transistors) so that the equalization function for the bitlines is performed by the restore circuit 80. The embodiment of FIGS. 7 and 8 show how the restore circuit 80 can be simplified (by removing the equalization transistors) so that the equalization function for the sense amplifier nodes is performed by the equalization transistors in the restore circuits 50 and 70.

The system and methods described herein may be embodied in other specific forms without departing from the spirit or essential characteristics thereof. The foregoing embodiments are therefore to be considered in all respects illustrative and not meant to be limiting.

What is claimed is:

1. A semiconductor memory device, comprising:
a. a sense amplifier comprising a sense node pair that is selectively connected to a bitline pair associated with a memory array; and
b. a first restore circuit connected to the sense amplifier that is controllable to precharge the sense node pair of the sense amplifier independent of equalize and precharge operations of the bitline pair.

2. The memory device of claim 1, wherein said first restore circuit is further controllable to maintain precharge of the sense node pair of the sense amplifier independent of a precharge operation on bitline pair.

3. The memory device of claim 1, wherein said first restore circuit comprises a transistor pair that charges the sense node pair of the sense amplifier and an equalization transistor that equalizes voltage on each node in the sense node pair.

4. The memory device of claim 3, wherein a multiplexer connects the bitline pair to the sense node pair of the sense amplifier when the memory array is selected, wherein the multiplexer is controllable to connect said equalization transistor of said first restore circuit to the bitlines of said bitline pair to equalize voltage on said bitlines.

5. The memory device of claim 4, wherein said multiplexer is controlled to stay on for an extended time interval in order for the equalization transistor of said first restore circuit to equalize voltage on said bitlines

6. The memory device of claim 4, wherein said first restore circuit is controllable to internally precharge the sense nodes of the sense amplifier independent of a state of the multiplexer.

7. The memory device of claim 4, and further comprising a second restore circuit comprising an equalization transistor connected to the bitlines of the bitline pair to equalize the voltage between bitlines of said bitline pair, wherein the multiplexer is controllable to connect the equalization transistor of the second restore circuit between sense nodes of the sense node pair to equalize voltage on the sense nodes.

8. The memory device of claim 7, wherein said multiplexer is controlled to stay on for an extended time interval in order for the equalization transistor of the second restore circuit to equalize voltage on the sense nodes.

9. The memory device of claim 1, and further comprising a second restore circuit that is controllable to precharge the bitline pair independent of precharge operations of the first restore circuit on the sense node pair.

10. A semiconductor memory device, comprising:
a. a first memory array comprising a plurality of memory cells and at least a first bitline pair associated with the first memory array;
b. a second memory array comprising a plurality of memory cells and at least a second bitline pair associated with the second memory array;
c. a sense amplifier comprising at least one sense node pair that is connected to the first bitline pair when the first memory array is selected and is connected to the second bitline pair when the second memory array is selected; and
d. a first restore circuit connected to the sense node pair of the sense amplifier that is controllable to precharge the sense node pair of the sense amplifier independent of equalize and precharge operations of the first and second bitline pairs.

11. The memory device of claim 10, wherein said first restore circuit is further controllable to maintain precharge of the sense node pair of the sense amplifier independent of a precharge operation on the first and second bitline pairs.

12. The memory device of claim 11, wherein said first restore circuit comprises a transistor pair that charges the sense node pair of the sense amplifier and an equalization transistor that equalizes voltage on each node in the sense node pair.

13. The memory device of claim 12, and further comprising a first multiplexer connected between the first bitline pair and the sense amplifier and a second multiplexer connected between the second bitline pair and the sense amplifier, wherein the first multiplexer is controllable to connect said equalization transistor of said first restore circuit to bitlines of said first bitline pair to equalize voltage on said bitlines in said first bitline pair, wherein the second multiplexer is controllable to connect said equalization transistor of said first restore circuit to bitlines of the second bitline pair to equalize voltage on the bitlines of said second bitline pair.

14. The memory device of claim 13, wherein said first restore circuit is controllable to internally precharge the sense nodes of the sense amplifier independent of states of the first and second multiplexers.

15. The memory device of claim 13, and further comprising a second restore circuit comprising an equalization transistor connected between bitlines of the first bitline pair to equalize the voltage between the bitlines of the first bitline pair, wherein the first multiplexer is controllable to connect the equalization transistor of the second restore circuit to the sense node pair of the sense amplifier to equalize sense nodes of the sense node pair.

16. The memory device of claim 13, wherein the first and second multiplexers are disabled indefinitely when the first and second memory arrays are not selected.

17. The memory device of claim 10, and further comprising a second restore circuit that is controllable to precharge the first bitline pair independent of precharge operations of the first restore circuit on the sense node pair, and a second restore circuit that is controllable to precharge the second bitline pair independent of precharge operations of the first restore circuit on the sense node pair.

18. A semiconductor memory device, comprising:
a. means for sensing voltage from a memory array, said means for sensing comprising a sense node pair that is selectively connected to a bitline pair associated with the memory array; and
b. first means connected to the sense node pair for precharging the sense node pair independent of equalize and precharge operations of the bitline pair.

19. The memory device of claim 18, wherein said first means comprises means for equalizing voltage on nodes of the sense node pair, and further comprising means for connecting the bitline pair to the sense node pair of the means for sensing when the memory array is selected, wherein said means for connecting further connects said first means to the bitline pair to equalize voltage on the bitlines of said bitline pair.

20. The memory device of claim 19, wherein said means for generating is controllable to internally precharge the sensing node pair independent of a state of said means for connecting.

21. The memory device of claim 19, and further comprising second means for equalizing connected to the bitline pair to equalize voltage on bitlines of said bitline pair, wherein said means for connecting is controllable to connect said second means to the sense node pair of said means for sensing to equalize voltage on sense nodes of said sense node pair.

22. A method for precharging a sense amplifier associated with a memory array in a semiconductor memory device, comprising internally precharging sense nodes of the sense amplifier independent of equalize and precharge operations on bitlines associated with the memory array.

23. The method of claim 22, wherein said internally precharging comprises activating a transistor pair internally connected to respective ones of the sense nodes.

24. The method of claim 22, and further comprising maintaining precharge of the sense nodes of the sense amplifier independent of a precharge operation on the bitlines.

25. The method of claim 22, and further comprising equalizing voltage on the bitlines by connecting to said bitlines an equalization transistor that is part of an restore circuit connected to the sense nodes.

26. The method of claim 22, and further comprising equalizing voltage on the sense nodes by connecting to the sense nodes an equalization transistor that is part of an restore circuit that is connected to said bitlines.
